(19) United States
(12) Patent Application Publication
(10) Pub. No.: US 2025/0162036 A1
(43) Pub. Date: May 22, 2025

(54) DIRECTIONAL RECRYSTALLIZATION PROCESSING OF ADDITIVELY MANUFACTURED METAL ALLOYS

(71) Applicant: Massachusetts Institute of Technology, Cambridge, MA (US)

(72) Inventors: Zachary C. Cordero, Westwood, MA (US); Dominic David. R. Peachey, Berkhamsted (GB); Christopher Pratt Carter, Cambridge, MA (US); Andres Garcia Jimenez, Boston, MA (US)

(73) Assignee: Massachusetts Institute of Technology, Cambridge, MA (US)

(21) Appl. No.: 18/839,592

(22) PCT Filed: May 5, 2022
(86) PCT No.: PCT/US2022/027845

§ 371 Date: Aug. 19, 2024

Related U.S. Application Data
(60) Provisional application No. 63/313,475, filed on Feb. 24, 2022.
(60) Provisional application No. 63/311,974, filed on Feb. 19, 2022.

(51) Int. Cl. B22F 10/64; B22F 10/28; B22F 10/66; B33Y 10/00; B33Y 40/20; C22F 1/10

(52) U.S. Cl. CPC B22F 10/64; B22F 10/66; B33Y 40/20; C22F 1/10; B22F 10/28; B33Y 10/00

(57) ABSTRACT

A method and apparatus used in preparing a recrystallized metal alloy involve a cooling medium and a heating element to create a cold zone and a hot zone. An additively manufactured metal alloy preform is drawn in a draw direction from the cold zone towards the hot zone to form the recrystallized metal alloy. The cold zone and the hot zone create a surface temperature gradient on at least a portion of the preform of at least about 10⁴ K m⁻¹. The step of drawing causes an average grain size of at least a portion of the preform to increase in a direction parallel to the draw direction.

### CROSS-REFERENCE TO RELATED APPLICATION(S)

This application claims the priority benefit, under 35 U.S.C. 119 (e), of U.S. Application No. 63/311,974, filed Feb. 19, 2022, entitled “Directional Recrystallization Processing Of Additively Manufactured Ni-Base Superalloys To Achieve Columnar Or Single-Crystal Grain Structures,” and U.S. Application No. 63/313,475, filed Feb. 24, 2022, entitled “Directional Recrystallization Processing Of Additively Manufactured Ni-Base Superalloys To Achieve Columnar Or Single-Crystal Grain Structures,” both of which are incorporated herein by reference in their entirety for all purposes.

### GOVERNMENT SUPPORT

This invention was made with government support under N00014-22-1-2036 awarded by the Office of Naval Research. The government has certain rights in the invention.

### BACKGROUND

Nickel-based superalloy components are used in the hot sections of gas turbines because of their exceptional creep strength and superior fatigue resistance at elevated temperatures. Such improved properties are due to the presence of ordered phases such as Ni₃Ti or Ni₃Al (e.g., γ′ phases) or insoluble oxide, boride, or carbide dispersoids in a face-centered cubic (FCC) matrix phase. The mechanical properties of Ni-based superalloys depend on the size, shape, concentration, and morphology of the strengthening phases (γ′, carbides, oxides, borides); the compositions of the different phases; and the grain size and shape of the superalloy. Coarse columnar (e.g., with an aspect ratio greater than 5 and a grain size greater than 100 μm) or single crystal grain structures suppress diffusional creep, resulting in slower creep rates and longer creep rupture times as compared to fine-grained equiaxed structures.

Nickel-based superalloys components are predominantly manufactured by investment casting or by machining from wrought material. Superalloys can also be manufactured via directional solidification processes, in which molten metal is poured into a mold and then solidified under a carefully controlled thermal gradient, using, for example, a Bridgman furnace. Superalloys manufactured via directional solidification processes can have creep-resistant coarse columnar or single crystal grain structures are typically manufactured via investment casting and directional solidification processes in which molten metal is poured into a mold and then solidified under a carefully controlled thermal gradient, using, for example, a Bridgman furnace. The molds used in such directional solidification processes can include internal features, such as integral cooling channels, which provide active cooling and permit higher operating temperatures in gas turbines. As-cast superalloy parts are post-processed using machining, heat treatment, and coating techniques.

There is a growing interest in using additive manufacturing technology to manufacture nickel-based superalloys. Laser powder bed fusion (LPBF), electron-beam additive manufacturing (EBAM), and Powder-Fed Directed Energy Deposition (DED) are additive manufacturing processes which form net-shaped superalloy components by melting powder feedstock, layer-by-layer, using a high-power laser or electron-beam. These additive manufacturing processes offer several advantages in comparison to conventional processing techniques, including higher yield, a large degree of design flexibility, reductions in the number of production steps, reduced scrappage, shorter lead times, and lower investment costs. Additive manufacturing provides high dimensional precision and the ability to create components with complex geometries and reduced weights. Compared to conventional casting, which typically uses a different ceramic mold for each component shape, additive manufacturing can be used to create different shape components with drastically shorter lead times. Additionally, additive manufacturing can be used to form oxide dispersion-strengthened superalloys, which offer improved creep resistance over conventional γ/γ′ alloys but which are difficult to form via conventional casting, forging, or machining processes due to their high-temperature strength and to challenges with oxide coarsening and agglomeration.

However, one issue with additive manufacturing is that the as-printed parts typically have a fine grain structure and a high dislocation density, which result in much higher diffusional creep rates compared to those in directionally solidified materials at equivalent temperature. As such, there is a need for post-processing heat treatments which can convert the fine grain structure of additively manufactured superalloys into coarse columnar or single crystal grain structures which suppress diffusional creep and enhance microstructural stability during elevated temperature service.

### SUMMARY

The inventors have recognized that conventional methods of post-processing heat treatment for additively manufactured superalloys result in superalloy components with fine grain structures and resulting poor mechanical properties. For example, U.S. Pat. No. 9,393,620 describes a method of preparing an additively manufactured turbine section part. The method specifies that the additively manufactured part is subjected to hot isostatic pressing prior to directional recrystallization. The order of this sequence does not provide results with the desired mechanical properties because the step of hot isostatic pressing prior to directional recrystallization reduces the high defect densities in the additively manufactured part, thereby reducing the driving force for recrystallization or else causing conventional recrystallization, resulting in substantially texture-free material with finer, more nearly equiaxed grains. Below a threshold driving force, the step intended to induce directional recrystallization instead only induces recovery, so that the resulting material does not have the desired coarse columnar grain structure.

The inventors have recognized that performing the step of directional recrystallization prior to any pressure and/or heat treatment that would reduce the driving force for recrystallization (e.g., stress relief annealing, hot isostatic pressing, super-solvus solutionizing, or sub-solvus aging heat treatments) creates a reproducible coarse columnar grained or single crystalline superalloy structure.

An embodiment of the technology includes a method of preparing a recrystallized metal alloy. The method includes providing a cooling medium and a heating element to create a cold zone and a hot zone. The method further includes drawing at least a portion of an additively manufactured preform in a draw direction from the cold zone towards the hot zone to form the recrystallized metal alloy. The cooling medium is provided as a liquid bath, a liquid spray, or a forced convection gas. The cold zone and the hot zone create a surface temperature gradient on at least a portion of the preform of at least about 10⁴ K m⁻¹. The step of drawing causes an average grain size of at least a portion of the preform to increase in a direction parallel to the draw direction.

The preform may include a superalloy comprising at least one of Ni, Co, Fe, or Nb. The preform may include a magnetic material comprising at least one of Ni, Co, or Fe. The preform may have a build axis corresponding to a build direction during additive manufacturing. During the step of drawing, the build axis of the preform may be oriented parallel to the draw direction. The draw direction may be a vertical direction, in which case the cooling medium may be provided as a liquid bath, a liquid spray, or a forced convection gas. Alternatively, the draw direction may be a horizontal direction, in which case the cooling medium is provided as a liquid spray or forced convection gas.

The heating element may include any means of creating a hot zone. For example, the heating element may be an induction coil, a resistive heater, an inductively heated susceptor, a laser beam, a focused light, or a flame. The surface temperature gradient may be at least about 10⁵ K m⁻¹. Prior to the step of drawing, the preform may have been additively manufactured by laser powder bed fusion (LPBF), electron beam additive manufacturing with point melting, or powder-fed directed energy deposition. If so, after the preform is additively manufactured, the preform is not subjected to any heat treatments that would substantially modify a dislocation density of the preform prior to the step of drawing. Prior to the step of drawing, the preform may have a dislocation density of about 10¹² m⁻² to about 10¹⁴ m⁻². The step of drawing may cause the average grain size to increase by at least a factor of 10. Prior to the step of drawing, the preform may have a crystallographic texture with at least 20% of its grains oriented with a <100> direction parallel to the draw direction with a tolerance of 15° misorientation. The step of drawing may substantially maintain the crystallographic texture in the additively manufactured preform.

The method may also include incorporating a functional grain structure grading into the metal alloy. Incorporating this grading includes at least one of: (a) varying a rate at which at least a portion of the preform is drawn while performing the step of drawing; (b) selectively drawing only non-continuous portions of at least a portion of the preform while performing the step of drawing; or (c) selectively heating non-continuous portions of at least a portion of the preform.

The metal alloy may include at least one of IN738 or IN738LC. If so, the heating element may heat the at least a portion of the preform to a surface temperature of about 1225° C. to about 1250° C. The step of drawing may be performed at a draw rate of about 1.0 mm/hr to about 5.0 mm/hr.

Another embodiment of the technology is an apparatus. The apparatus includes a cooling medium having a heat transfer coefficient of about 100 W m⁻² K⁻¹ to about 40,000 W m⁻² K⁻¹, a heating element configured to provide a hot zone capable of heating at least a portion of an additively manufactured preform, and a means for drawing the at least a portion of the preform in a draw direction from the cooling medium through the hot zone. The cooling medium and the hot zone are capable of creating a surface temperature gradient on at least a portion of the preform of at least about 104 Km⁻¹.

Another embodiment of the technology is a recrystallized metal alloy comprising at least one of Ni, Co, Fe, or Nb prepared by a process that includes additively manufacturing a preform along a build direction and directionally recrystallizing the preform to form the recrystallized metal alloy. Directional recrystallization includes drawing at least a portion of the preform in a draw direction parallel to the build direction from a cold zone provided by a cooling medium towards a hot zone provided by a heating element. The recrystallized metal alloy has an average grain size in the draw direction larger than an average grain size in the draw direction in the preform and an average grain size aspect ratio greater than 5.

The step of additively manufacturing the preform may include laser powder bed fusion (LPBF), electron beam additive manufacturing with point melting, or powder-fed directed energy deposition. The preform may have a dislocation density of about 10¹² m⁻² to about 10¹⁴ m⁻². The recrystallized metal alloy may have a dislocation density of about 10¹⁰ m⁻² to about 10¹² m⁻². Both the preform and the recrystallized metal alloy may have a crystallographic texture with at least 20% of grains oriented with a <100> direction parallel to the draw direction with a tolerance of 15° misorientation.

The step of additively manufacturing the preform may include incorporating a grain selector feature or single crystal seed into the preform. The step of additively manufacturing the preform may include incorporating a spatial compositional gradient into the preform. The recrystallized metal alloy may have at least one of a columnar grain structure or a single crystal grain structure. The recrystallized metal alloy may include a functional gradation of grain size or material composition. The recrystallized metal alloy may include at least one of IN738 or IN738LC, A286, 718, 625, 909, 690, 600, H230, H282, HX, H188, 939, Rene65, Merl72, IN100, Rene108, CM247LC, 713C, Rene N2, Rene N4, Rene N5, Rene N6, CMSX4, CMSX10, RR1000, RR1073, C103, ODS alloys, and/or other similar alloys.

All combinations of the foregoing concepts and additional concepts discussed in greater detail below (provided such concepts are not mutually inconsistent) are part of the inventive subject matter disclosed herein. In particular, all combinations of claimed subject matter appearing at the end of this disclosure are part of the inventive subject matter disclosed herein. The terminology used herein that also may appear in any disclosure incorporated by reference should be accorded a meaning most consistent with the particular concepts disclosed herein.

### BRIEF DESCRIPTIONS OF THE DRAWINGS

The skilled artisan will understand that the drawings primarily are for illustrative purposes and are not intended to limit the scope of the inventive subject matter described herein. The drawings are not necessarily to scale; in some instances, various aspects of the inventive subject matter disclosed herein may be shown exaggerated or enlarged in the drawings to facilitate an understanding of different features. In the drawings, like reference characters generally refer to like features (e.g., functionally and/or structurally similar elements).

FIG. 1 shows an additive manufacturing schematic.

FIG. 2A shows a directional recrystallization apparatus.

FIG. 2B shows another directional recrystallization apparatus.

FIG. 2C shows a directional recrystallization apparatus.

FIG. 2D shows an additively manufactured preform metal alloy with a grain selector.

FIG. 3A shows a scheme for preparing a directional recrystallized metal alloy.

FIG. 3B shows a first scheme for preparing a directional recrystallized metal alloy with a grain structure gradient.

FIG. 3C shows a second scheme for preparing a directional recrystallized metal alloy with a grain structure gradient.

FIG. 3D shows a third scheme for preparing a directional recrystallized metal alloy with a grain structure gradient.

FIG. 4A shows a grain orientation map of an as-printed metal alloy with a strong <001> fiber texture parallel to the build direction.

FIG. 4B shows the volume fraction of grains with a <100> pole with a 15° tolerance of the draw and build directions in directional recrystallized metal alloys as a function of draw rate. FIG. 4C is a table showing the data in FIG. 4B.

FIG. 5 shows differential scanning calorimetry (DSC) of additively manufactured Ni-based superalloy IN738LC.

FIG. 6 shows the temperature and temperature gradient measured across a directional recrystallization apparatus in the draw direction.

FIG. 7A shows an etched micrograph of additively manufactured Ni-based superalloy that was subjected to directional recrystallization on its right side.

FIG. 7B shows an electron backscatter diffraction (EBSD) image of the material in FIG. 7A.

FIG. 7C shows hardness values for the material in FIG. 7A.

FIG. 7D shows the temperature profile used for directional recrystallization in FIG. 7A.

FIG. 8A shows additively manufactured Ni-based superalloy samples subjected to directional recrystallization at different draw rates.

FIG. 8B is a graph of draw rate vs. grain size in additively manufactured Ni-based superalloy.

FIG. 9 shows a functionally graded additively manufactured Ni-based superalloy with a grain size gradient.

### DETAILED DESCRIPTION

Directional recrystallization is a post-processing heat treatment of additively manufactured metal alloys that overcomes some of the difficulties conventionally faced when post-processing additively manufactured metal alloys. These difficulties include poor control of crystal structure and lack of reproducibility. Conventionally post-processed metal alloys often have disordered crystal structures and poor mechanical properties.

To improve the mechanical properties of polycrystalline additively manufactured components, the components are conventionally treated with a combination of stress relief annealing, hot isostatic pressing, super-solvus solutionizing, and sub-solvus aging heat treatments. This sequence relieves the residual stresses and high defect densities present in the as-printed material and produces substantially dislocation free microstructures with larger grains and desired precipitate morphologies. The precipitate morphology desired depends on its application and can vary in average precipitate size and volume fraction. For example, desired morphology may include a core-shell structure, a duplex precipitate size distribution, or a morphology where precipitates decorate and strengthen grain boundaries. But even after these conventional post-processing treatments are performed, the high temperature creep resistance of additively manufactured materials is substantially lower than that of directionally solidified metal alloys, which have columnar polycrystalline or single crystalline grain structures. Additionally, due to the metastable nature of the as-printed microstructure, these conventional post-processing treatments can be challenging to control, resulting in low reproducibility.

In contrast, directional recrystallization is a controllable and reproducible method of post-processing additively manufactured metal alloys. Additively manufactured metal alloys prepared via directional recrystallization have large columnar polycrystalline or single crystal grain structures with improved mechanical properties, including improved high temperature creep resistance. Creep resistance is the stress level that produces a nominal strain in a certain period of time. Small increases in grain size may greatly increase steady state creep resistance. Materials with lower steady state creep rates resist material failure for longer periods of time.

Metal additive manufacturing processes can create intricate components that are difficult to form with conventional processing methods. However, the metal materials made with additive manufacturing (sometimes called “as-printed materials”) often have fine grain structures and poor high-temperature creep properties.

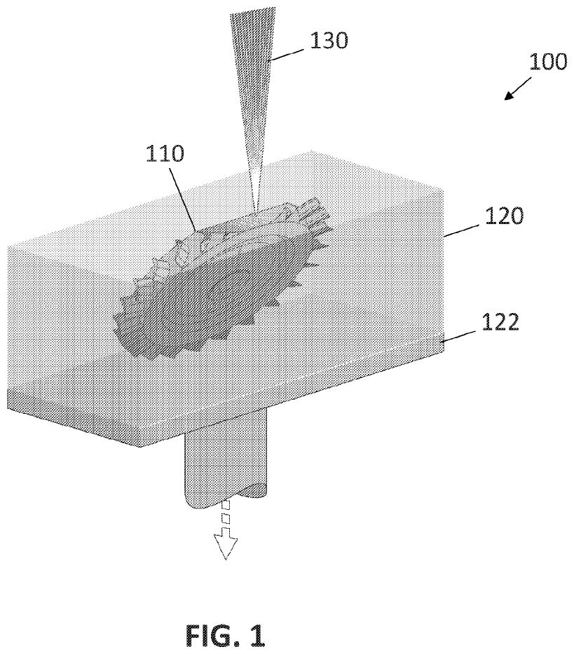

FIG. 1 shows a part of a laser powder bed fusion (LPBF) additive manufacturing system 100 used to make metal alloy preform component 110. The system 100 uses a high-power-density laser to create a laser beam 130 that selectively melts and fuses metallic powders together in a metallic powder bed 120. The metallic powders in the powder bed 120 include the elements in ratios that make up the resulting material composition of the preform component 110. The laser beam 130 scans a cross-section of the component 110, melting the metal particles in the powder bed 120 together. When a layer is finished, the platform 122 moves down and a new layer of powder is spread over the top so that the laser beam 130 can scan a new cross-section of the component 110. This process repeats until the component 110 is fully formed. The additively manufactured material has a build axis corresponding to the build direction during additive manufacturing.

The component 110 is a metal alloy that include two or more metals, at least one of which is nickel (Ni), cobalt (Co), iron (Fe), or niobium (Nb). The metal alloy can be a superalloy or a precursor to a superalloy including at least one of Ni, Co, Fe, or Nb. A superalloy is a metal alloy with the ability to operate at a high fraction of its melting point due to its high temperature mechanical properties. Superalloys are used to make many high-temperature components, including turbine blades (e.g., for industrial gas or aeroengines), turbine vanes, combustor cans, high-temperature dies, rocket nozzles, leading edges, compressor blades, and compressor vanes. The metal alloy can also be a magnetic alloy. The magnetic alloys can include at least one of Ni, Co, or Fe.

Instead of LPBF, another melt-based additive manufacturing process may be used to prepare the preform. For example, electron beam additive manufacturing with point melting (EBAM), or powder-fed directed energy deposition (DED) may be used to create the preform component 110. EBAM is a similar process to LPBF except that an electron beam is used to melt the metallic powders instead of a laser beam. Powder-fed DED uses either a laser beam, electron beam, or plasma arc to heat a metal powder as it is ejected from one or more nozzles.

Because of the extreme thermal cycling during melt-based additive manufacturing processes, the resulting preforms have a high density of dislocations, about 10¹² m⁻² to about 10¹⁴ m⁻² (e.g., 10¹² m⁻², 10¹³ m⁻², or 10¹⁴ m⁻²). The high dislocation density in the preform acts as a driving force for directional recrystallization. Consequently, the preform is preferably not subjected to any post-processing treatments (e.g., heat treatments and/or pressure treatments) that might substantially modify the dislocation density in the preform prior to post-processing the preform with directional recrystallization.

In an example, the preform is additively manufactured with a crystallographic texture. The crystallographic texture (also called preferred orientation) is the statistical distribution of grains in the material that are oriented in a particular direction. Crystallographic texture can affect mechanical properties of a material, including deformation mechanisms. As an example, the preform may be printed with at least 15% (e.g., 15%, 20%, 25%, 30%, 35%, or 40%, and preferably at least 20%) of its grains oriented with a <100> direction parallel to the build direction with a tolerance of 5° to 15° (e.g., 5°, 10°, or 15°, preferably at 10° or less) misorientation. The build direction may be coincident with the loading direction and the long axis of the preform.

The additively manufactured preform may incorporate a grain selector feature and/or a single crystal seed into the preform as it is manufactured or after it is printed. The grain selector feature, constriction, and/or single crystal seed may have a preferred phase and orientation and may induce the formation of this phase and orientation in the material during directional recrystallization. The grain selector feature may be single crystalline or polycrystalline. The grain selector may be cut off after processing.

Additive manufacturing may also be used to incorporate a functionally graded spatial compositional gradient into the preform. Materials with compositional gradients may have mechanical properties and/or chemical stabilities that make them well-suited for certain applications. As described below, the compositional gradient is substantially maintained during and after directional recrystallization of the component.

In one version of directional recrystallization, a hot zone passes along the length of an additively manufactured preform component. A few grains in the component are nucleated in the hot zone and grow competitively within the moving hot zone in the component. During this heat treatment, one or more elongated recrystallized grains consume finer grains in the component as the finer grains enter the hot zone, resulting in a coarse columnar grain structure with columnar grains oriented along the length of the component. A similar mechanism may result in a single crystalline grain structure through incorporation of a grain selector and/or seed crystal. During recrystallization, competitive growth of the grains may permit growth of a single grain through a constriction. The single grain may consume the rest of the polycrystalline preform. Competitive growth of the grains may permit growth of a single grain through a constriction. The single grain may consume the rest of the polycrystalline preform to form a single crystalline structure.

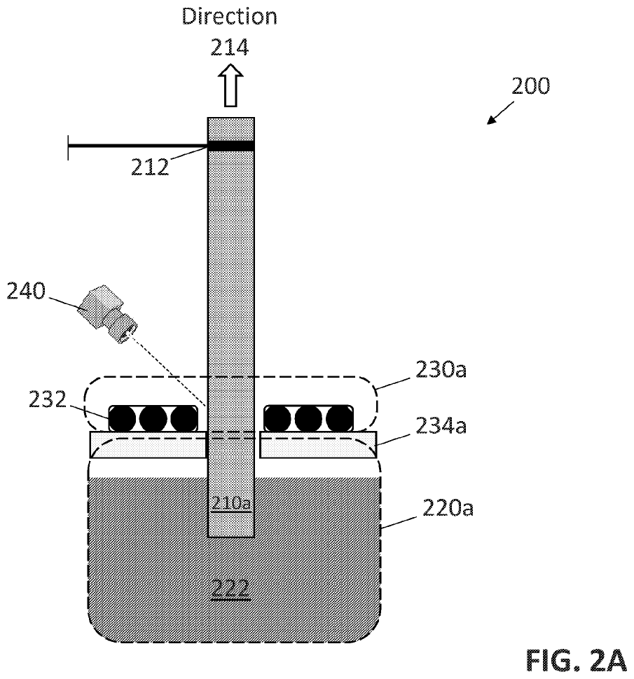

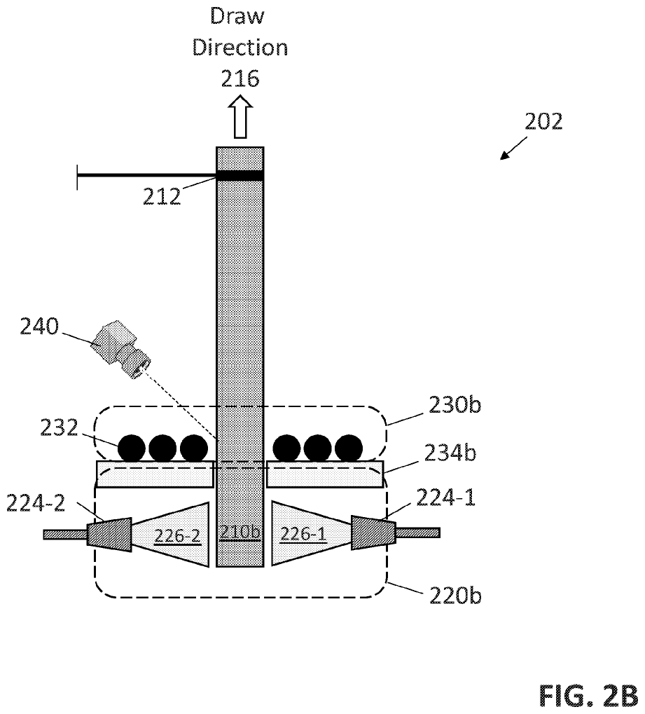

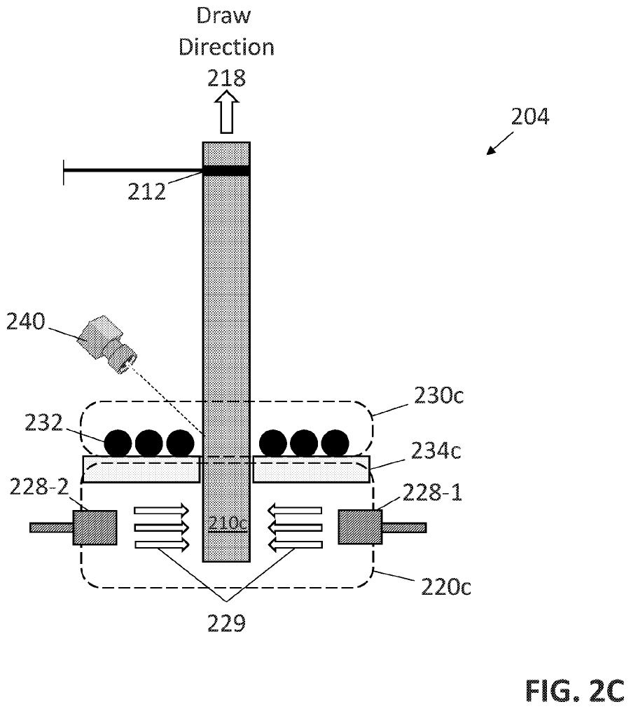

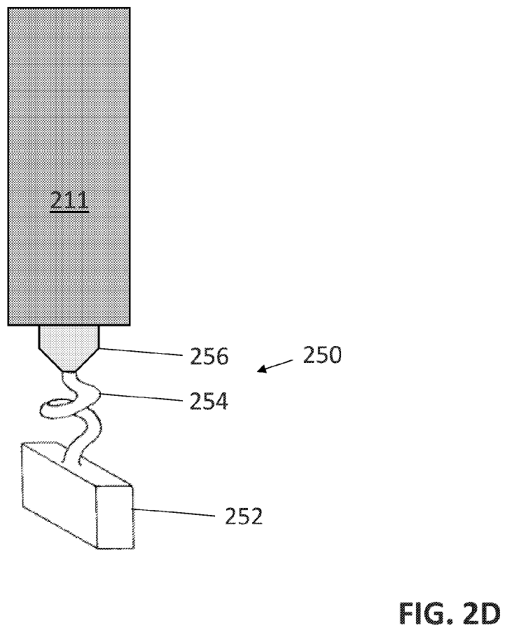

FIG. 2A shows an apparatus 200 for directionally recrystallizing an additively manufactured component 210a. The apparatus 200 is used to transform the component 210a from a preform, which has a fine grain structure (e.g., about 1 μm to about 100 μm) and a high dislocation density, to a directionally recrystallized component, which has a coarse (also called large) columnar crystal structure with a lower dislocation density or a single crystal structure. The component 210a is made of an additively manufactured metal alloy. The metal alloy component 210a may have a length of about 1 cm to about 1 m.

The apparatus includes a cold zone 220a and a hot zone 230a, which together create a temperature gradient (also called a thermal gradient). The temperature gradient is the temperature difference versus distance between the cold zone 220a and the hot zone 230a. During operation of the apparatus 200, the temperature gradient between the cold zone 220a and the hot zone is at least about 10⁴ Km⁻¹ (e.g., about 10⁴ Km⁻¹, about 10⁵ Km⁻¹, or about 10⁶ Km⁻¹), as measured at the surface of the component 210a. The distance between the cold zone 220a and the hot zone 230a is about 0.2 cm to about 10 cm (e.g., 0.2 cm, 0.4 cm, 0.5 cm, 0.6 cm, 0.7 cm, 0.8 cm, 0.9 cm, 1 cm, 1.2 cm, 1.4 cm, 1.6 cm, 1.8 cm, 2 cm, 2.5 cm, 3 cm, 4 cm, 5 cm, 6 cm, 7 cm, 8 cm, 9 cm, or 10 cm). For example, a thermal gradient of 10⁵ Km⁻¹ may result from a temperature increase of about 1000 K over a distance of 1 cm.

The cold zone 220a includes a cooling medium, which in apparatus 200 is a liquid bath 222. The cooling medium (whether as a liquid bath 222 as in apparatus 200, a liquid spray as in apparatus 202 below, or a forced convection gas as in apparatus 204 below) may have a high heat transfer coefficient. The high heat transfer coefficient helps maintain part of the component 210a at a lower temperature before it reaches the hot zone 230a. The part of the component 210a that has not entered the hot zone 230a is kept cold using the cooling medium to prevent premature elimination of the dislocations present in the as-printed preform version of the component 210a. The cold temperature is about 273 K to about 0.4 times the solidus temperature of the metal alloy. The dislocations in the preform are a driving force of primary recrystallization in directional recrystallization of the component 210a. Directional recrystallization may also include secondary recrystallization. The presence of component 210a in the cold zone 220a before it is moved to the hot zone 230a creates a steep temperature gradient in the component 210a between the portion of the component in the cold zone 220a and the portion of the component in the hot zone 230a. The steep temperature gradient maintains the preform's high dislocation density and/or fine grain size leading into the recrystallization front in the hot zone 230a and may prevent or substantially reduce grain growth and recrystallization ahead of the hot zone since this may dissipate the driving force for recrystallization. If the temperature gradient is too small, the driving force may be lost or substantially reduced through grain growth and recrystallization ahead of the hot zone, so that the preform's grains become less columnar, akin to heat treatment with a furnace.

The cooling medium's heat transfer coefficient varies depending on its substance (e.g., water or oil), the cooling medium's phase (liquid and/or gas), and any forced movement or agitation. The cooling medium's heat transfer coefficient may be about 100 W m⁻² K⁻¹ to about 40,000 W m⁻² K⁻¹ (e.g., at least about 100 W m⁻² K⁻¹, at least about 200 W m⁻² K⁻¹, at least about 500 W m⁻² K⁻¹, at least about 1,000 W m⁻² K⁻¹, at least about 5,000 W m⁻² K⁻¹, at least about 10,000 W m⁻² K⁻¹, at least about 20,000 W m⁻² K⁻¹, at least about 30,000 W m⁻² K⁻¹, or at least about 40,000 W m⁻² K⁻¹).

The liquid bath 222 may include water, a water-based solution, an oil (e.g., a mineral oil based quench oil), a molten salt (e.g., mixtures of nitrates of sodium and potassium; mixtures of sodium chloride (NaCl), potassium chloride (KCl), calcium chloride (CaCl₂), sodium carbonate (Na₂CO₃), and barium chloride (BaCl₂)), or a molten metal (e.g., molten tin). The bath 222 may be a stagnant liquid. Alternatively, the bath 222 may be stirred and/or may be boiling. In a version, the bath 222 is preferably stirred to increase its heat transfer coefficient and to better cool the portion of the component 210a in the cold zone 220a. In one version, the volume of liquid in the bath 222 may be large enough so that not all of the liquid evaporates before the directional recrystallization process is finished. In another version, the liquid in the bath 222 may be actively cooled to maintain a fixed temperature. In another version, liquid may be continuously added to the bath 222 to maintain a constant volume during directional recrystallization.

The hot zone 230a includes one or more heating elements 232 configured to heat at least a portion of the additively manufactured preform 210a. The heating elements 232 may include one or more of an induction coil, an induction coil with a susceptor, a resistive heater, a laser beam, a focused light, or a flame. The heating elements 232 are arranged in a geometry to provide substantially even heating to all surfaces of the component 210a as it passes through the hot zone 230a. If the heating elements 232 are susceptors or resistance heating elements, they may have tubular (e.g., like a tube furnace) shapes and the preform may be passed through the hollow center of the heating element tube. If the heating elements 232 are induction heaters, they may be tubular or flat pancake type shapes. Flat pancake shaped heating elements 232 may be preferably for heating a preform having a flat shape. The highest temperature in the hot zone 230a may be downstream of the heating elements 232 away from the cold zone 220a.

The highest temperature in the hot zone 230a provided by the heating elements 232 is selected based at least in part on the type of metal alloy being processed. If the component includes a precipitation hardening alloy, the highest temperature in the hot zone 230a is between the solvus temperature and the solidus temperature of γ′ phase of the metal alloy. To form a columnar grain structure, the dissolution of γ′ may be used to remove the Zener pinning effect it exerts on the grain boundaries. If the component includes a dispersion-strengthened alloy, the highest temperature in the hot zone 230a is about 90% of the alloy's solidus temperature to the alloy's solidus temperature (e.g., 90%, 95%, 99%, or 99.95% of the solidus temperature). As an example, the highest temperature range for additively manufactured IN738LC, low carbon nickel-based superalloy, was about 1225° C. to about 1250° C., and preferably about 1235° C., where the γ′ solvus temperature was 1180° C. and the solidus temperature was 1240° C.

The distance between the heating elements 232 and the liquid bath 222 is selected to induce a sharp temperature gradient between the cold zone 220a and the hot zone 230a. The distance between the heating elements 232 and the liquid bath 222 may depend on the directional recrystallization temperature, the cooling medium temperature, and the desired temperature gradient. This distance is kept short to produce the sharp temperature gradient ahead of the hot zone 230a. In one example, the distance is about 1 cm and the temperature increases by about 1000 K between the cold zone 220 and the hot zone 230a. In another example, the distance close to 0 to create a higher temperature gradient.

In a version, the apparatus 200 optionally includes a baffle or heat shield 234a. The heat shield 234a may be placed between the heating elements 232 and the liquid bath 222 or other cooling medium along the draw direction 214 to act as a thermal barrier. The thermal barrier may increase heating efficiency and the temperature gradient between the hot zone 230a and the cold zone 220a. The apparatus 200 may also optionally include an optical pyrometer. An optical pyrometer 240 measures temperatures in the range of about 700° C. and about 4,000° C. The optical pyrometer 240 may be used to measure the temperature of the surface of the component 210a as it passes through the hottest part of the hot zone 230a, and these measurements may be used as feedback to control the heating of the heating elements 232.

As the component 210a is drawn through the hot zone 230a, it is transformed into the directionally recrystallized version of the component 210a. The component 210a is drawn from the cold zone 220a through the hot zone 230a. Draw rates may be tuned relative to the growth rate of the recrystallized grains in the component 210a, which may vary depending on the chemical composition of the component 210a. If the draw rate is faster than the growth rate of the recrystallized grains, the recrystallization front may not keep up with the movement of the component 210a through the hot zone, so that the component 210a may not recrystallize or may only partially recrystallize, resulting in smaller and/or less columnar grain sizes. On the other hand, if the draw rate is much slower than the growth rate of the recrystallized grains, then the directionality of recrystallization may partially or completely break down. When the directionality of recrystallization breaks down, the recrystallized grains may lose their directional orientation and become equiaxed instead of columnar. Draw rates faster or slower than the recrystallization growth rate may result in the component 210a having finer and/or more equiaxed grains.

The draw rate at which the component 210a is drawn through the apparatus 200 varies from about 0.1 mm/hr to about 400 mm/hr (e.g., 0.1 mm/hr, 0.5 mm/hr, 1 mm/hr, 2.5 mm/hr, 5 mm/hr, 10 mm/hr, 22 mm/hr, 100 mm/hr, 200 mm/hr, or 400 mm/hr). As an example, the step of drawing is performed at a draw rate of about 1.0 mm/hr to about 5.0 mm/hr when directionally recrystallizing additively manufactured IN738LC. The draw rate may be constant to induce a uniform grain structure in the component 210a or may be varied to induce a gradient grain structure, as discussed in more detail below.

The apparatus 200 includes a means for drawing at least a portion of the component 210a in the draw direction 214 from the cooling medium through the hot zone. The drawing means may be a stepper motor, a conveyor, or another form of linear actuator that pulls or pushes the component 210a through the cold zone 220a and the hot zone 230a. The component 210a may be mounted to the drawing means using a specimen mount 212 connected to the drawing means.

The draw direction 214 is the direction in which the component 210a is moved through the apparatus 200. In apparatus 200 the draw direction 214 is vertically upward or at an angle less than 60° from the vertical axis. In this way, gravity helps separate the component 210a from the liquid in the liquid bath 220a as the component 210a moves through the apparatus 200. After moving through the hot zone 230a, the directionally recrystallized version of the component 210a may be gradually cooled to room temperature and/or may be quenched with water before being subjected to additional post-processing steps.

Since the orientation of the grains in the directionally recrystallized component 210a are substantially aligned with the draw direction 214, the component 210a may be specifically oriented in the apparatus 200 so that the large columnar grains in the directionally recrystallized component 210a are oriented in a preferred direction. For example, if the component 210a has a loading axis, the component 210a may be oriented so that the draw direction 214 is parallel with the loading axis to provide higher creep resistance along the loading axis. The component 210a may also be oriented in the apparatus 200 in relation to the additive manufacturing build axis. For example, the component 210a may be oriented so that the draw direction 214 is parallel to the build axis.

FIG. 2B shows an apparatus 202 for directionally recrystallizing an additively manufactured component 210b. The apparatus 202 includes many of the same components as apparatus 200. The apparatus 202 includes a cold zone 220b and a hot zone 230b, which together forms a temperature gradient to transform the component 210b from a fine-grained preform to a directionally recrystallized component.

The cold zone 220b includes a cooling medium, which in apparatus 202 is one or more liquid sprays. The apparatus 202 in FIG. 2B is shown with two spray nozzles 224-1 and 224-2 providing two liquid spray streams 226-1 and 226-2 but may alternatively have a single spray nozzle or more than spray nozzles. The spray nozzles 224-1 and 224-2 direct the spray streams 226-1 and 226-2 toward the preform version of the component 210b so that at least part of the spray streams contacts the preform. The spray streams 226-1 and 226-2 spray cool the preform to cool it before it reaches the hot zone 230b. The spray streams 226-1 and 226-2 may spray continuously during directional recrystallization. The spray streams 226-1 and 226-2 may evenly coat all sides of the preform 210b as it moves through the cold zone 220b. The nozzles 224-1 and 224-2 may rotate around the preform to coat the preform's surfaces. Alternatively, the nozzles 224-1 and 224-2 may be stationary and positioned to spray the preform's surfaces. The means for moving the preform 210b through the apparatus in the draw direction 216 may rotate the preform 210b around the axis of the draw direction 216 to facilitate uniform cooling. In a version, an array of spray nozzles may be arranged in a circle to create a spray stream in the shape of an annulus where the preform 210b may be drawn through the center of the annulus. The liquid spray streams 226-1 and 226-2 may include water, a water-based solution, or an oil.

The hot zone 230b includes one or more heating elements 232 configured to heat at least a portion of the component 210b, as described with respect to apparatus 200. The distance between the heating elements 232 and the edge of the liquid spray streams 226-1 and 226-2 is the same distance as between the heating elements 232 and the liquid bath 222 in the apparatus 200. In a version, the apparatus 202 optionally includes a baffle or heat shield 234b to prevent ingress of the spray into the hot zone. The heat shield 234b may be placed between the heating elements 232 and the liquid spray streams 226-1 and 226-2.

The draw direction 216 in apparatus 202 may be vertically upward, horizontally, or at any angle in between. The orientation of the draw direction 216 may be selected to help separate the liquid spray streams 226-1 and 226-2 from the hot zone 230b.

FIG. 2C shows an apparatus 204 for directionally recrystallizing an additively manufactured component 210c. The apparatus 204 includes many of the same components as apparatus 200. The apparatus 204 includes a cold zone 220c and a hot zone 230c, which together create a temperature gradient to transform the component 210c from a fine-grained preform to a directionally recrystallized component.

The cold zone 220c includes a cooling medium, which in apparatus 204 is a forced convection gas 229. The apparatus 204 can include one or more pumps or fans to move the gas. FIG. 2C shows the apparatus 204 having two gas ports 228-1 and 228-2 that direct the forced gas 229 toward the preform so that at least a part of the forced gas 229 moves over and past the surface of the component 210c in the cold zone 220c, transferring heat from the component 210c to the forced gas 229. The forced gas 229 may be directed continuously during directional recrystallization. The forced gas 229 may be evenly directed toward all sides of the preform 210c as it moves through the cold zone 220c. The gas ports 228-1 and 228-2 may rotate around the preform to coat the preform's surfaces. Alternatively, the gas ports 228-1 and 228-2 may be stationary and positioned to spray the preform's surfaces. The means for moving the preform 210c through the apparatus in the draw direction 218 may rotate the preform 210c around the axis of the draw direction 218 to facilitate uniform cooling. In a version, an array of gas ports may be arranged in a circle to direct forced gas in the shape of an annulus where the preform 210c may be drawn through the center of the annulus.

The forced gas may include air, nitrogen, another gas with a high thermal conductivity, or a combination thereof. The forced gas 229 has a heat transfer coefficient of 100 W m⁻² K⁻¹ to about 1000 m⁻² K⁻¹. For example, forced air may have a heat transfer coefficient of about 500 W m⁻² K⁻¹.

The hot zone 230c includes one or more heating elements 232 configured to heat at least a portion of the component 210c, as described with respect to apparatus 200. The distance between the heating elements 232 and the edge of the forced gas 229 is the same distance as between the heating elements 232 and the liquid bath 222 in the apparatus 200. In a version, the apparatus 204 optionally includes a baffle or heat shield 234b. The heat shield 234b may be placed between the heating elements 232 and the forced gas 229 to prevent or substantially reduce movement of the forced gas 229 into the hot zone 230c.

The draw direction 218 in apparatus 204 may be oriented in any direction. Since the apparatus 204 does not use a liquid cooling medium, it does not need to consider separating a liquid cooling medium from the hot zone in selecting the orientation of the draw direction 218.

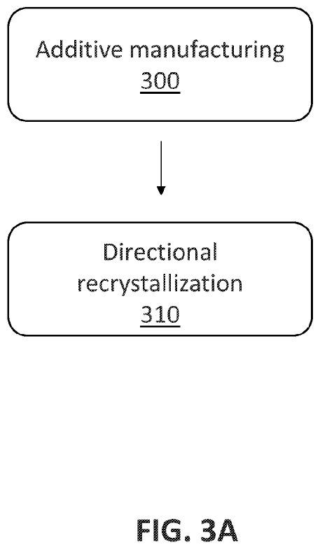

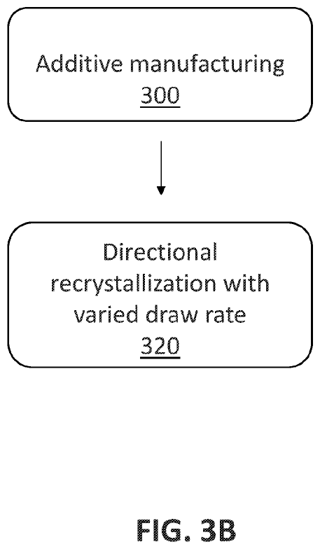

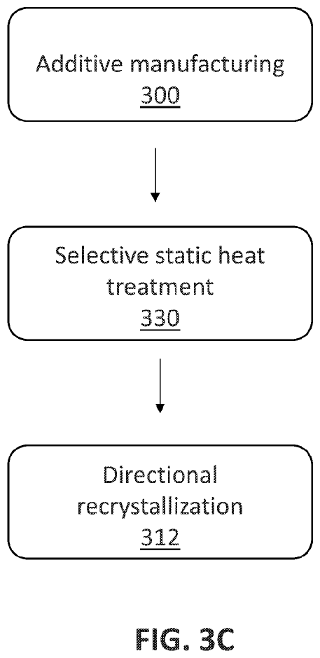

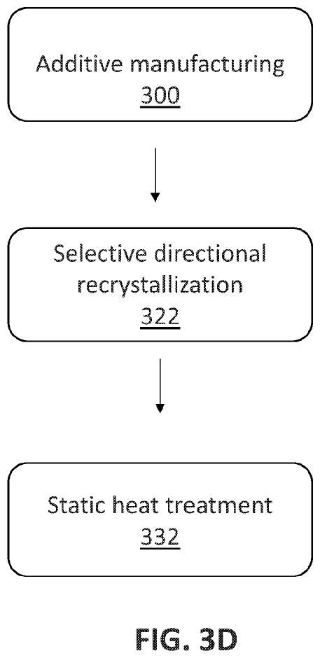

FIG. 3A illustrates a method of preparing an additively manufactured metal alloy with a coarse columnar or single crystalline grain structure. The method includes the step 300 of additively manufacturing a metal alloy preform. The additive manufacturing step 300 uses a melt-based additive manufacturing process (e.g., LPBF, EBAM with point melting, or powder-fed DED).

Once the metal alloy preform is formed in step 300, the metal alloy preform is post-processed with the step 310 of directional recrystallization to create the directionally recrystallized additively manufactured metal alloy. The step of directional recrystallization 310 may use any of the apparatuses shown in FIGS. 2A-2C and any of the parameters described with respect to these apparatuses. The step of directional recrystallization 310 converts the fine grain structure of the as-printed metal alloy to a coarse columnar or single crystalline grain structure.

Between steps 300 and 310, the metal alloy is not subjected to any pressure and/or heat treatment that would reduce the dislocation density in the metal alloy preform. The metal alloy preform has a high density of dislocations that act as the driving force for directional recrystallization. Reducing the dislocation density in the preform would reduce the driving force for directional recrystallization. Post-processing treatments that are avoided between steps 300 and 310 include stress relief annealing, hot isostatic pressing, super-solvus solutionizing, and sub-solvus aging heat treatments.

The step 310 of directionally recrystallizing the metal alloy causes an average grain size of at least a portion of the metal alloy to increase in a direction parallel to the apparatus's draw direction by a factor of about 10 to about 1,000,000. As an example, the large columnar crystal structure in a recrystallized metal alloy may have a grain size of about 100 μm or larger, and preferably 500 μm or larger, and a grain aspect ratio (ratio of mean grain size along the loading/build/draw directions to that transverse to those directions) of 3 or larger, and preferably at least 20. The step 310 of directional recrystallization may also decrease the dislocation density in the component from a density of about 10¹² to about 10¹⁴ m⁻² to a density of about 10¹⁰ to about 10¹² m⁻².

The step 310 of directionally recrystallizing the metal alloy can be used to manipulate its crystallographic texture. Texture manipulation may be done to minimize thermal stresses expected when the component is in service. Components post-processed using step 310 may substantially inherit the fiber texture of the as-printed preform. For example, prior to directional recrystallization, a preform may have a crystallographic texture with about 15% to about 80% of its grains, and preferably at least 20% (and more preferably at least 30%) of its grains oriented with a <100> direction parallel to the draw direction with a tolerance of less than or equal to 15° misorientation, and preferably less than or equal to 10° misorientation. During the step 310 of directionally recrystallizing the component, it substantially maintains its crystallographic texture. For example, the directionally recrystallized component may maintain about 10% to about 80% (e.g., 10%, 30%, 60%, 75%, or 80%) of its crystallographic texture. Draw rate may be adjusted to change the amount of texture maintained.

The method shown in FIG. 3A can be used to create many different types of additively manufactured materials with directionally recrystallized grain structures. For example, this method may be used to make many different superalloys, including precipitation-hardened γ/γ′ alloys and dispersion-strengthened superalloys. Superalloys are alloys with the ability to operate at a high fraction of their melting point, and often have excellent mechanical strength, resistance to thermal creep deformation, good surface stability, and resistance to corrosion or oxidation. Precipitation-hardened alloys are strengthened through the precipitation of an ordered intermetallic phase and do not include dispersoids. Dispersion-strengthened superalloys include a dispersion of fine nano-scale oxides that improve high temperature creep resistance. Dispersion-strengthened superalloys may also be precipitation hardened. Examples of precipitation-hardened superalloys that may be made include nickel-based superalloys IN718, IN738, IN738LC, and IN939 (where IN is used as shortform for Inconel). Dispersion-strengthened superalloys include MA754, MA758, and MA6000.

Draw rates for dispersion-strengthened alloys may range from 1 mm/hr to 1000 mm/hr. Annealing temperatures for the directional recrystallization of dispersion-strengthened superalloys exceeds 90% of the material solidus temperature. In joint precipitation-hardened and dispersion-strengthened alloys, directional recrystallization will begin at temperatures above the γ′ solvus temperature.

The metal alloy may include one or more major elements in a weight percentage greater than 5%, including nickel, chromium, cobalt, iron, aluminum, tungsten, tantalum, titanium, rhenium, niobium, and molybdenum. The metal alloy may include one or more minor elements in a weight percentage less than or equal to 5%, including molybdenum, tungsten, niobium, titanium, tantalum, aluminum, cobalt, hafnium, rhenium, zirconium, ruthenium, chromium, boron, and carbon. For example, the metal alloy may include MA 738; MA753; MA754; MA755; MA757; MA758; MA760; MA6000; MA953; MA956; MA957; HDA8077; PM1000; PM2000; PM3030; TD-Ni; TD-NiCr; TD-NiCrFe; TD-NiCrAl; TD-NiCrAlY; DS-IN-738; DS-Ni; DS-NiCr; X-127; DTY552; 14 YWT; 9YWT; Alloy 98; TMO-2; TMO-7; TMO-8; TMO-9; TMO-19; TMO-20; CM247LC+Y203; 14Cr Steel+Y203; IN625+Y203; NiCoCr HEA; AT-259/HA-8077; AT-264; AT-265; AT-266; AM1; AM3; CM186LC; CM247LC; CMSX-2; CMSX-3; CMSX-4; CMSX-6; CMSX-10; EPM-102; GTD-111; GTD-222; IN100; IN-713LC; IN-738LC; IN-792; IN-939; Mar-M002; Mar-M246; Mar-M247; Mar-M200Hf; Mar-M421; MC2; MC-NG; MX4; Nasair 100; PWA1422; PWA1426; PWA1480; PWA1483; PWA1484; PWA1487; PWA1497; Rene 41; Rene 80; Rene 88DT; Rene 95; Rene 104; Rene 108; Rene 125; Rene 142; Rene 220; Rene N4; Rene N5; Rene N6; RR1000; RR2000; SRR99; TMS-75; TMS-138; TMS-162; Alloy 10; Alloy 22; Astroloy C-263; Hastelloy S; Hastelloy X; Haynes 230; Haynes 242; Haynes 282; Haynes R-41; Incoloy 800; Incoloy 801; Incoloy 802; Incoloy 909; Incoloy 925; Inconel 600; Inconel 601; Inconel 617; Inconel 625; Inconel 690; Inconel 706; Inconel 718; Inconel 738; Inconel 740; Inconel X750; LSHR; ME3; MERL-76; Nimonic 75; Nimonic 80A; Nimonic 90; Nimonic 105; Nimonic 115; Nimonic 263; Nimonic 901; Nimonic PE16; Nimonic PK33; N18; Pyromet 31; Pyromet 860; Udimet 500; Udimet 520; Udimet 630; Udimet 700; Udimet 710; Udimet 720; Udimet 720LI; Waspaloy; and/or K625.

As another example, a nickel-based superalloy IN738L or IN738LC may have the following composition by weight:
7% to 10% of cobalt;
14% to 18% of chromium;
1.4% to 2.1% of molybdenum;
1.9% to 2.7% of tungsten;
2% to 5% of aluminum;
2% to 6% of titanium;
1.5% to 2.1% of tantalum;
0.04% to 0.10% of zirconium;
0.08% to 1.6% of carbon;
0.006% to 0.013% of boron;
0.6% to 1.2% of niobium;
   and the balance comprising nickel along with residual elements in trace amounts. As another example, the superalloy IN738LC may have the following composition by weight:
8.4% of cobalt;
16% of chromium;
1.7% of molybdenum;
2.3% of tungsten;
3.5% of aluminum;
4.0% of titanium;
1.9% of tantalum;
0.07% of zirconium;
0.12% of carbon;
0.0093% of boron;
0.91% of niobium;

and the balance comprising nickel along with residual elements in trace amounts.

The metal alloy may also be magnetic. For example, the magnet may be a Nd—Fe—B permanent magnet, AlNiCo, FeCo (e.g., hiperco or vacoflux), an Fe—Si transformer core material, a SmCo permanent magnet, a Sm—Co—Nb—C permanent magnet, or a Sm—Co—Nb permanent magnet.

Directionally recrystallizing the metal alloy improves its mechanical properties, including its high temperature creep resistance, making it well-suited for high temperature applications, including those in gas turbine and aerospace applications. For example, the additively manufactured component that is directionally recrystallized may be a compressor blade, a compressor vane, a compressor stator, a compressor airfoil, a blisk, a shrouded blisk, an impellor, an inducer, an exducer, a diffusor, a de-swirler, a volute, a combustor, a flame holder, a flame stabilizer, a fuel burner, a combustion liner, an interstage seal, a shroud, a shroud support and/or hanger, an airflow accelerator, a turbine blade, a shrouded turbine blade, a turbine vane, a turbine nozzle, a turbine airfoil, a turbine stator, a mixer, a nozzle flap, a nozzle panel, a high-temperature die, a rocket nozzle, a leading edge, or a part thereof. As an example, the component may be part of an industrial land-based gas turbine having a weight of about 20 lbs. to about 80 lbs. (e.g., 50 lbs.) and being about 10 cm to about 80 cm tall (e.g., 40 cm tall), or part of an aeroengine, having a weight of about 0.5 lbs. to about 5 lbs. (e.g., 2 lbs.) and being about 2 cm to about 15 cm tall (e.g., 10 cm tall).

Any of the methods or apparatuses described above may be used to create new additively manufactured features on a conventionally cast component or for repairing a component. For example, if a portion of a turbine blade is damaged, the damaged portion may be removed with machining and replaced with a directionally recrystallized additively manufactured metal alloy.

The additively manufactured and directionally recrystallized components have a different microstructure than conventionally created components. Conventionally cast components may have a eutectic solidification structure that is not present in the additively manufactured and directionally recrystallized components. Conventionally forged components may have equiaxed grains or grains that follow the flow fields (i.e., the plastic flow of the material during forming), while additively manufactured and directionally recrystallized components do not. Conventionally cast materials may have micro-scale dendritic structures, with local interdendritic regions enriched in certain alloying elements. These interdendritic regions may extend for 1 mm to 10 mm along the growth direction, with dendrite spacing on the order of about 100 microns. Coarse interdendritic regions may be absent from additively manufactured materials or may be substantially fewer than in conventionally cast materials. The as-printed material's structure may include some local interdendritic regions, but fewer than that of a conventionally cast material. Additively manufactured materials may not have interdendritic porosity.

As-printed additively manufactured material may have a structure that reflects the scanning strategy and melt pattern. For example, in LPBF, the grain shape may resemble the scanning strategy, with grains preferentially growing along the laser scanning direction. The microstructure of an as-printed additively manufactured material may also be much finer than conventionally cast materials. A transverse cross-section of an as-printed LPBF manufactured metal alloy may have a fish-scale microstructure consistent with the individual melt passes during LPBF.

To obtain a single crystal structure in the component with directional recrystallization, a seed crystal, grain selector, or geometric constriction may be used. A seed crystal is a small single crystal that is used as a base to nucleate single crystal growth. A grain selector is a geometric feature with a starter block, a selector block, and a connector part. The selector block has a specific shape that induces single crystal growth. The shape of the grain selector may be a spiral, a restrictor, or an angle. The component may include a geometric constriction that is very thin for a reasonable length so that only one columnar grain may fit through the constriction and out-compete the other grains, resulting in a single crystalline structure. The seed crystal, grain selector, or constriction may be welded to the additively manufactured preform or may be incorporated into the component during additive manufacturing. If the seed crystal or grain selector is incorporated during additive manufacturing, it may be positioned as a substrate upon which the preform component is additively manufactured.

FIG. 2D shows an example of an additively manufactured preform 211 with a grain selector 250. The grain selector 250 may be incorporated with the preform 211 during additive manufacturing or may be welded to the preform 211 after additive manufacturing. The grain selector 250 includes a starter block 252, a selector block 254, and a connector part 256. The connector part 256 connects the selector block 254 to the preform 211. The selector block 254 in FIG. 2D has a spiral pig-tail shape that induces single crystal growth in the preform 211 during directional recrystallization. The grain selector 250 facilitates the growth of only one crystal during directional recrystallization so that a single crystal forms during directional recrystallization.

After the component has been directionally recrystallized, additional post-processing methods may be employed. For example, the component may be subjected to hot isostatic pressing, machining, surface finishing, coating, precipitation heat treating, stress relief annealing, super-solvus solutionizing, sub-solvus aging heat treatments, and/or quality control processes.

### Functional Grading

A metal alloy component may be functionally graded by varying its composition and/or grain structure over some or all of a volume of the component. Functional grading may be used to change the mechanical and/or chemical properties of the metal alloy component. For example, functional grading can be used to change the metal alloy's corrosion resistance, thermal resistance, malleability, toughness, and/or creep-resistance over a specific volume of the metal alloy.

The metal alloy's grain structure may be functionally graded to selectively enhance fatigue or creep performance. For the application of a turbine blade or compressor blade, the component may have a fine grain structure in the portion(s) of the component where thermal and mechanical fatigue is a concern (e.g., near the blade root, on the trailing edge, on the leading edges, and/or on the tip of the blade). The component may have a coarse columnar grain structure in the blade body to improve creep resistance. Functional grading of grain structure cannot be done using conventional forging or casting processes.

There are several ways to induce a functionally graded grain size in the recrystallized metal alloy component by modifying the methods described above. FIG. 3B illustrates a first method to create an additively manufactured metal alloy component with a grain size gradient. In step 300, the component preform is additively manufactured similarly to step 300 described with respect to FIG. 3A. Once formed, the component reform is post-processed in step 320 using directional recrystallization in a manner similar to that described with respect to FIG. 3A, except that instead of using a constant draw rate, the draw rate during the step of directional recrystallization is varied to induce a grain size gradient. As described above, when the draw rate is faster or slower than the recrystallization growth rate, the grain sizes of the recrystallized metal alloy may be smaller than if the draw rate is substantially similar to (e.g., ±20 mm/hr) the recrystallization growth rate. The grain size in a functionally graded component may change monotonically or oscillate in a fixed volume. For example, a component may have an average grain size of about 40-60 μm in one portion of the component and an average grain size of about 450-550 μm in another portion of the component, with the average grain size gradually increasing between the two portions. The distance between the two portions may be as small as about 1 mm.

FIG. 3C illustrates another method to create an additively manufactured metal alloy component with a grain size gradient. After additively manufacturing the component preform in step 300, the component preform is post-processed in the step 330 using a selective static heat treatment before the step 312 of directional recrystallization. The step 330 of selective static heat treatment selectively anneals (e.g., via recrystallization and/or recovery) non-continuous portions of the component to reduce dislocations and other internal stresses. During directional recrystallization 312, the component is drawn through the apparatus at a steady draw rate. The portions of the component that were heat treated in step 330 maintain small equiaxed grains during directional recrystallization in step 312 while the portions of the component that were not heat treated directionally recrystallize to form large columnar grain structures. The reason that the heat treated portions do not directionally recrystallize is because those portions lack the dislocation density and/or fine grain size that act as the driving force for directional recrystallization.

FIG. 3D illustrates another method to create an additively manufactured metal alloy component with a grain size gradient. After additively manufacturing the component preform in step 300, the component preform is selectively directionally recrystallized in step 322. In step 322, non-continuous portions of the component are processed with directionally recrystallization. Non-continuous directional recrystallization is done by only sending non-continuous portions through the hot zone of the directional recrystallization apparatus. After step 322, the whole component is subjected to a static heat treatment 332 to anneal the portions of the component that were not subjected to directional recrystallization in step 322. The portions not subjected to directional recrystallization maintain small equiaxed grains while the directionally recrystallized portions have large columnar grains.

Functional grading of the component can also be a compositional gradient. Compositional gradients may be formed in the component preform during additive manufacturing. Any compositional gradient formed in the preform is maintained during directional recrystallization. Compositional gradients may be used to protect a component against hot corrosion. For example, if the component is used as a turbine blade, the root of the turbine blade may have a higher concentration of alloying elements that protect against hot corrosion (e.g., chromium) while the blade itself may have a higher concentration of γ′ forming elements (e.g., aluminum and/or titanium) and a lower chromium concentration to improve creep properties and avoid chromia volatilization. The concentrations of the different alloying elements may be varied. For example, the compositional gradient may include a transition between two terminal compositions. The transition distance may be two to five times the melt pool depth during additive manufacturing (e.g., about 1 mm in powder bed fusion and about 1 cm in directed energy deposition processes). It is not possible to create a compositional gradient with conventional casting or forging methods.

### Example of Directional Recrystallization

Additively manufactured IN738LC is a Ni-based superalloy with many applications, including for use in the blades of industrial gas turbines. The directional recrystallization behaviors of additively manufactured IN738LC were characterized through a parameter study in which the temperature in the hot zone and the draw rate were each independently varied. Recrystallization began when the surface temperature in the hot zone exceeded the γ′ solvus of IN738LC at 1180° C. Varying the draw rate from 1 mm/hr to 100 mm/hr while maintaining a fixed surface temperature of 1235° C. in the hot zone and a thermal gradient on the order of 105° C./m ahead of the hot zone showed that a draw rate of 2.5 mm/hr increased the grain size, giving a mean grain size of 650 um with some grains nearly 1 cm long. Specimens processed under these optimal conditions also inherited the fiber texture of the as-printed material. Faster or slower draw rates resulted in finer, more equiaxed grains and also degraded the fiber texture. Close inspection of a sample of IN738LC quenched during directional recrystallization revealed a discrete primary recrystallization front whose position followed the γ′ solvus isotherm. Behind the recrystallization front, metal to carbon (MC) carbides exhibited rapid coarsening, likely due to accelerated coarsening kinetics as carbide-forming elements (e.g., Ti) initially sequestered in γ′ went back into solution. These MC carbides in turn limited grain growth in the transverse direction through Zener pinning. The results demonstrated how directional recrystallization of Ni-based superalloys achieved large columnar grains, manipulated crystallographic texture to minimize thermal stresses expected in service, and functionally graded the grain structure to selectively increase fatigue strength and/or creep performance.

Directional recrystallization experiments were performed using a liquid water bath in the cold zone and in air in the hot zone on rods of IN738LC (Ni with nominal composition weight percent 8.4% Co, 3.5% Al, 4.0% Ti, and 2.3% W) manufactured through laser powder bed fusion. The directional recrystallization specimens of 3 mm diameter and 83 mm length were cut from larger 1 cm diameter blanks using wire electrical discharge machining, with the axis of the rod parallel to the build direction. Low-resolution scanning electron micrograph (SEM) confirmed the good print quality, meaning with few if any cracking defects in the whole cross-sectional area viewed.

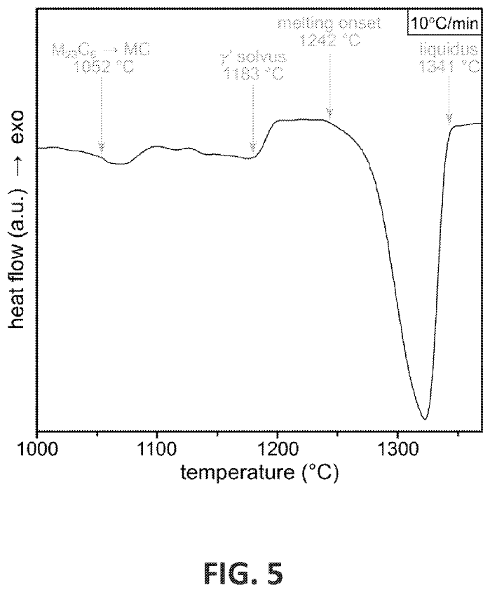

The rods were mounted vertically to the directional recrystallization apparatus 200 shown in FIG. 2A, using a steel set screw shaft collar with ceramic spacers between the specimens and the holder. The ceramic spacers provided thermal insulation, preventing heat transfer from the rod to the mount. The samples were inductively heated to surface temperatures between 1220° C. and 1245° C. with the temperature controlled using a two-color optical pyrometer that compensated for variable emissivity. The separation between the coil and the water bath was approximately 0.7 mm; this short distance produced a sharp temperature gradient of order 10⁵ K/m ahead of the hot zone. Each sample was drawn through the hot zone at draw rates varying from 1 mm/hr to 100 mm/hr. Experiments performed included a series with a fixed peak temperature of 1235° C. and variable draw rates of 1 mm/hr, 2.5 mm/hr, 5 mm/hr, 10 mm/hr, 22 mm/hr and 100 mm/hr as well as a temperature series at 1220° C., 1235° C. and 1245° C., all at a draw rate of 22 mm/hr. The temperature range for the experiments was chosen to be between the solvus and solidus temperatures (1180° C. and 1240° C., respectively) of the base alloy, as determined through differential scanning calorimetry (DSC) shown in FIG. 5. After completion of the heat treatment, specimens were quenched in water.

Recrystallized materials were subsequently mechanically polished and etched using Kalling's No. 2 (5 g CuCl₂ in 100 ml hydrochloric acid and 100 ml ethanol). The grain structure of recrystallized samples was studied using optical and electron microscopy. Electron back-scattered diffraction (EBSD) was used to probe the texture in the samples. The samples were polished chemo-mechanically using a colloidal silica suspension for 12 minutes. Diffraction patterns were collected using an EDAX Hikari Super camera on a ThermoFischer Scios2 microscope operated under an accelerating voltage of 30 kV.

COMSOL multiphysics was used to simulate the temperature distribution along a rod during directional recrystallization with the apparatus 200 having a hot zone surface temperature of 1235° C. Thermal convection, thermal conduction, and thermal radiation were used to describe heat transport in the liquid, the rod, and the rode side surfaces, respectively. An extra fine tetrahedral mesh was used for the finite element calculation. To approximately simulate the resistive heating effect of the induction coil a boundary heat source was set on the surface of the sample and power applied over this 4 mm region until the surface temperature reached steady state at 1235° C. The simulations showed that the temperature profile around the sample next to the coil was determined by coil geometry while the overall temperature distribution along the specimen was dominated by the cooling effects of the water bath. Additionally, the hotter region of the sample had a significant horizontal temperature drop of 15-20° C. from the surface to the center of the sample.

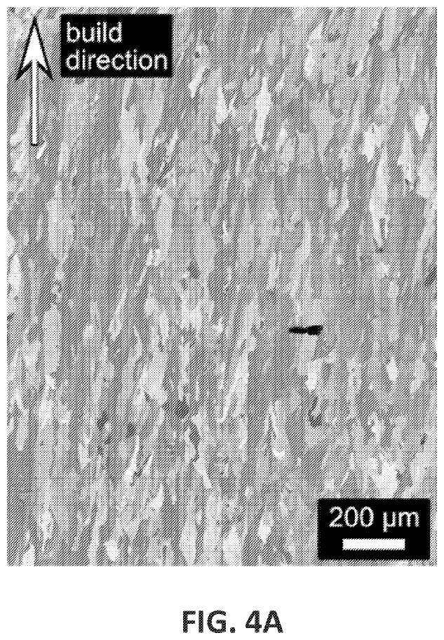

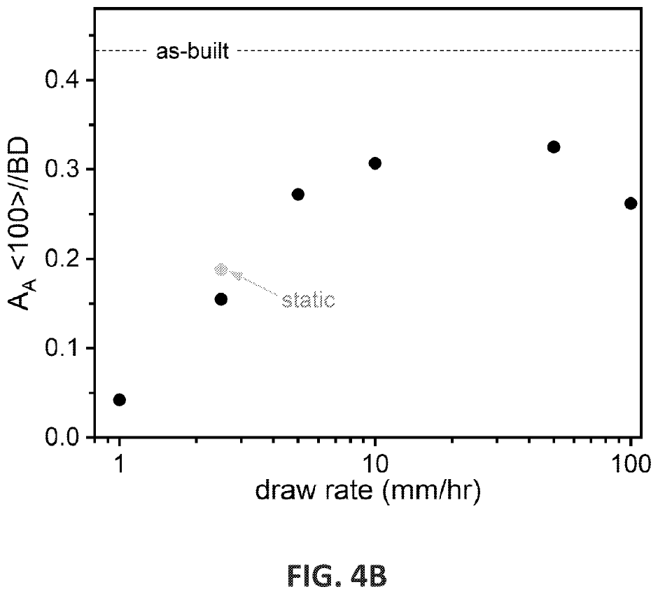

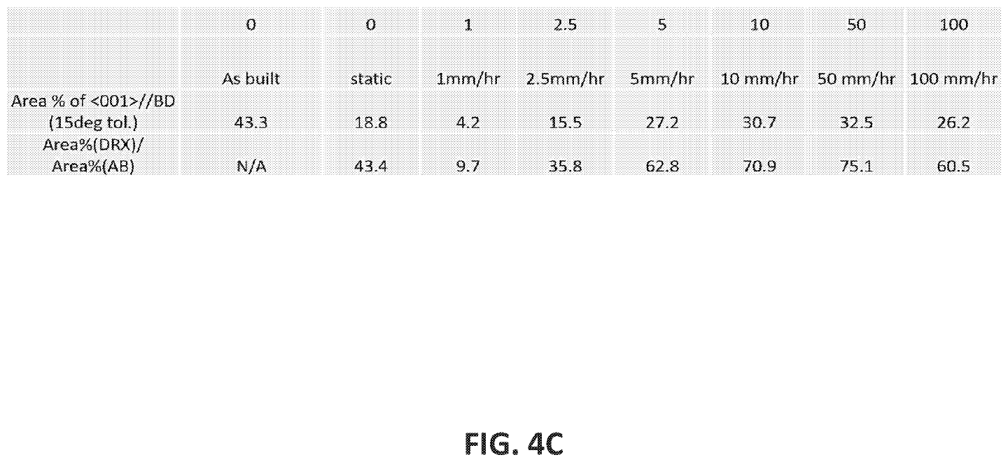

FIG. 4A shows a grain orientation map of the as-printed IN738LC with respect to the build direction, revealing a strong <001> fiber texture parallel to the build direction. The printed material contained no observable γ′ and a dispersion of fine nanoscale carbides in the as-fabricated state. FIG. 4B shows amount of texture in the directionally recrystallized IN738LC inherited from its as-printed preform. The texture is measured as the volume fraction of the directionally recrystallized IN738LC object with a <100> pole in the draw direction with a 15°, tolerance as a function of draw rate during directional recrystallization. The texture in the directionally recrystallized IN738LC is compared to the as-printed (also called as-built) preform material, in which 43% of the area of the object is textured with a <100> pole.

FIG. 4C is a table showing the percent area of the object with this <100> texture and a comparison of the percent textured area of the directionally recrystallized alloy (DRX) as compared to the percent textured area in the as-printed material (AB). An object that was post-processed with a static heat treatment had a texture area percentage of about 18%. In contrast, when the object was subjected to directional recrystallization, the object had a percent area texture of about 15.5% at a draw rate of 2.5 mm/hr, about 27% at a draw rate of 5 mm/hr, about 30% at a draw rate of 10 mm/hr, and about 33% at a draw rate of 50 mm/hr.

FIG. 5 is a DSC thermogram during the first heating of additively manufactured IN738LC. The DSC shows where recrystallization set in. The DSC results showed a broad exotherm between 500° C. and 820° C. due to γ′ precipitation; a small endothermic reaction starting at around 1070° C., which, without being bound by any theory, may be linked to the M23C6 solvus temperature; the γ′ solvus temperature at 1183° C.; a solidus temperature at 1240° C.; and a liquidus of 1341C. The temperature window between the γ′ solvus and the solidus was where recrystallization may have occurred. Recrystallization began when the peak temperature was above the γ′ solvus and below the solidus temperature.

Vickers microhardness tests of the IN738LC heat treated at different temperatures indicated that hardening starts at about 600° C., which, without being bound by any theory, may be a result of γ′ precipitation. Above 1100° C. the object's hardness substantially lessened which, without being bound by any theory, may be due to the γ′ dissolution occurring at about 1180° C. At temperatures greater than 1200° C., the hardness value of the component stabilized, with only slight variations possible due to localized grain orientation effects.

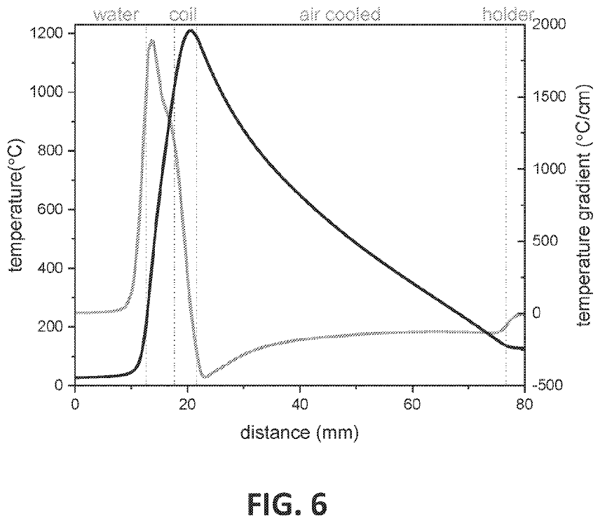

FIG. 6 shows the temperature and temperature gradient at the surface of the metal alloy component 210a measured across the directional recrystallization apparatus 200 in the draw direction 214. The apparatus 200 used a liquid water bath 222 as the cooling medium in the cold zone 220a. The temperature of the portion of the component 210a immersed in the liquid bath 222 was at about 20° C. The portion of the component 210a in the hot zone 230a was at a temperature of up to about 1235° C. near the heating element 234a, which was an induction coil. The temperature of the component 210 downstream of the hot zone 230a was gradually cooled in air and its surface temperature decreased to room temperature. The temperature gradient in the hot zone was about 1700° C./cm.

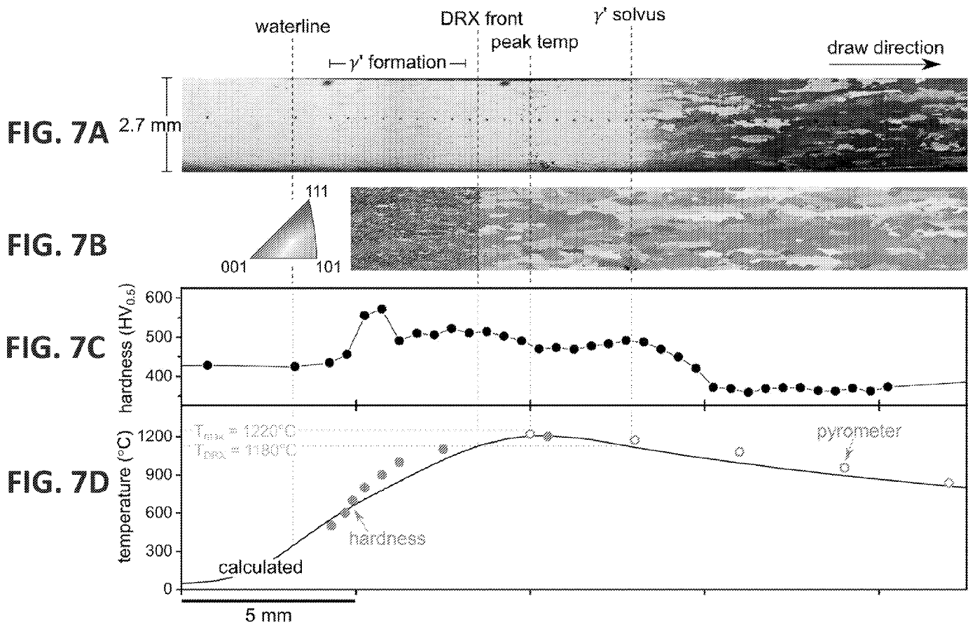

FIGS. 7A-7D show an etched micrograph, an electron backscatter diffraction (EBSD) image, Vickers hardness values, and the surface temperatures, respectively, of the IN738LC component as it moved through the directional recrystallization apparatus 200. The draw rate was 2.5 mm/hr from left to right and the temperature in the hot zone was 1235° C. The temperature profile in FIG. 7D was calculated using finite element analysis (FEA) and validated experimentally using hardness and pyrometer measurements.

Due to the nature of the Kallings etchant, the optical micrograph only showed contrast where the γ′ particles in the component were sufficiently large. Therefore, the main region of contrast was to the right where the component had undergone directional recrystallization and gradual cooling so that the portion of the component had large γ′ grains that had precipitated during cooling. The formation of the large γ′ grains resulted in a decrease in hardness due to overaging, as shown in FIG. 7C. Additionally, a slight contrast was shown in the optical micrograph preceding the recrystallization front in the component, where the component had been heated and γ′ had started to precipitate from the γ′-free as-built preform. The onset of γ′ precipitation corresponds to a peak in the hardness profile in FIG. 7C

The hardness measurements in FIG. 7C taken along the length of the component were used to calculate the temperature profile shown in FIG. 7D. The temperature data calculated using hardness values is shown as solid circles. The temperature data measured with the optical pyrometer on the surface of the component is shown as open circles. The solid line indicates the calculated FEA simulation values.

Immediately after the γ′ formation region, moving in the draw direction, the directional recrystallization front is visible in the EBSD color map in FIG. 7B. The recrystallization front is the sudden transition from fine as-printed material to large columnar grains. The recrystallization front occurred at an approximate temperature of about 1180° C., which is close to the γ′ solvus temperature. Without being bound by any theory, for columnar grain formation, the dissolution of γ′ may be used to remove Zener pinning caused by the γ′ phase. The EBSD map indicated that the <001> texture of the as-printed preform was inherited by the directionally recrystallized region of the component, which showed a preferential <001> fiber texture.

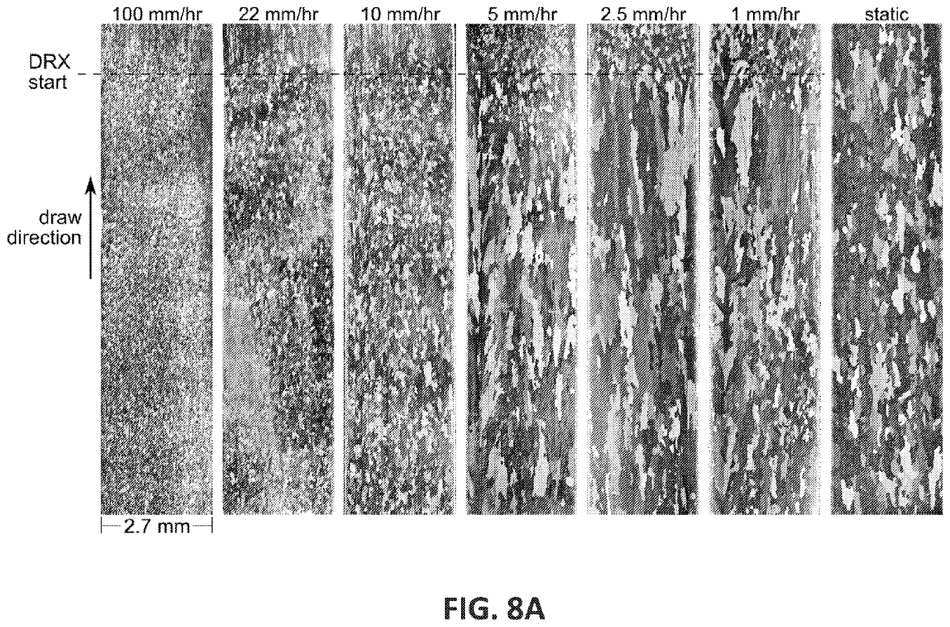

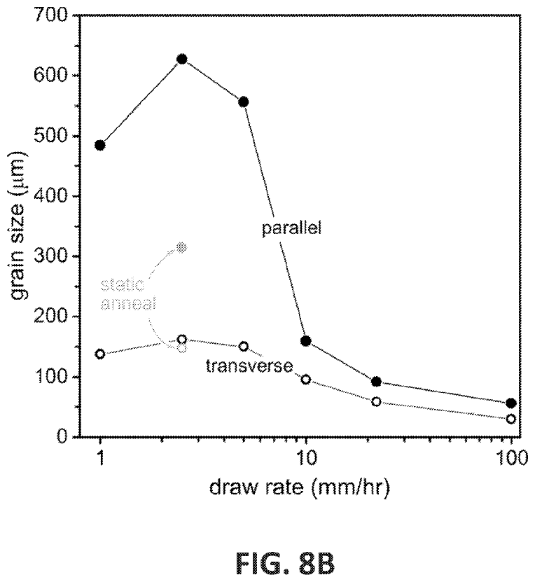

FIG. 8A shows additively manufactured Ni-based superalloy samples subjected to directional recrystallization at different draw rates. FIG. 8A shows optical images of IN738LC samples processed at different draw rates of about 1 mm/hr to about 100 mm/hr as compared to a static sample. The static sample was treated in a furnace with no longitudinal temperature gradient using the same temperature-time profile as that experienced by the 2.5 mm/hr sample during DRX, as determined by the COMSOL simulation. At all draw rates, fully recrystallized material was observed with substantially elongated grains produced only at draw rates less than or equal to 5 mm/hr.

FIG. 8B is a graph of draw rate vs. grain size in additively manufactured Ni-based superalloy. FIGS. 8A and 8B, show that grain size of directionally recrystallized materials varies with the draw rate, with the largest grains at 2.5 mm/hr. With draw rates faster than 2.5 mm/hr, the growth of the recrystallized grains cannot keep up with the movement of the hot zone, so directional growth breaks down. However, if the hot zone velocity is too slow (e.g., 1 mm/hr), normal grain growth occurs ahead of the hot zone, which reduces the driving force for columnar grain formation resulting in a more equiaxed microstructure.

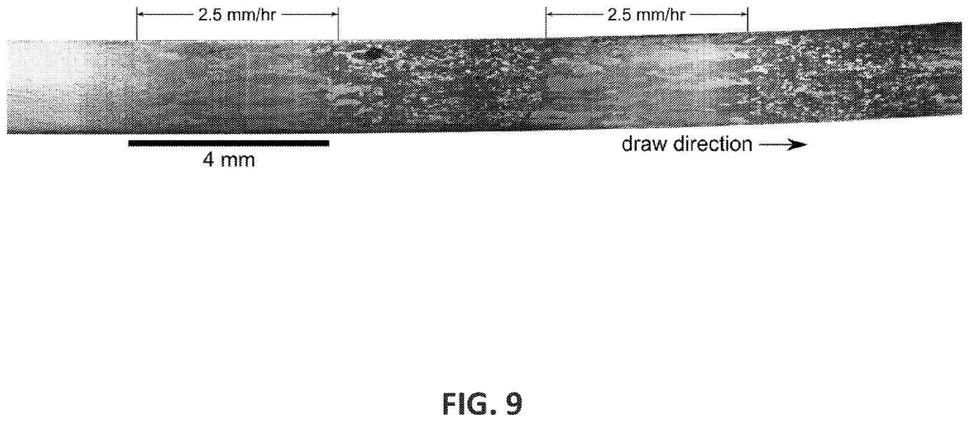

FIG. 9 shows a functionally graded additively manufactured IN738LC superalloy with a functionally graded grain structure. The microstructure grading was obtained by precisely varying the draw rate during directional recrystallization. The draw rate was alternated between 2.5 mm/hr and 50 mm/hr over 6 mm intervals. The resulting grain structure features equiaxed fine grain regions, where the component was exposed to the hot zone at the faster draw rate, and coarse columnar grain regions, where the component was exposed to the hot zone at the slower draw rate.

### CONCLUSION

While various inventive embodiments have been described and illustrated herein, those of ordinary skill in the art will readily envision a variety of other means and/or structures for performing the function and/or obtaining the results and/or one or more of the advantages described herein, and each of such variations and/or modifications is deemed to be within the scope of the inventive embodiments described herein. More generally, those skilled in the art will readily appreciate that all parameters, dimensions, materials, and configurations described herein are meant to be exemplary and that the actual parameters, dimensions, materials, and/or configurations will depend upon the specific application or applications for which the inventive teachings is/are used. Those skilled in the art will recognize or be able to ascertain, using no more than routine experimentation, many equivalents to the specific inventive embodiments described herein. It is, therefore, to be understood that the foregoing embodiments are presented by way of example only and that, within the scope of the appended claims and equivalents thereto, inventive embodiments may be practiced otherwise than as specifically described and claimed. Inventive embodiments of the present disclosure are directed to each individual feature, system, article, material, kit, and/or method described herein. In addition, any combination of two or more such features, systems, articles, materials, kits, and/or methods, if such features, systems, articles, materials, kits, and/or methods are not mutually inconsistent, is included within the inventive scope of the present disclosure.

Also, various inventive concepts may be embodied as one or more methods, of which an example has been provided. The acts performed as part of the method may be ordered in any suitable way. Accordingly, embodiments may be constructed in which acts are performed in an order different than illustrated, which may include performing some acts simultaneously, even though shown as sequential acts in illustrative embodiments.

All definitions, as defined and used herein, should be understood to control over dictionary definitions, definitions in documents incorporated by reference, and/or ordinary meanings of the defined terms.

The indefinite articles “a” and “an,” as used herein in the specification and in the claims, unless clearly indicated to the contrary, should be understood to mean “at least one.”

The phrase “and/or,” as used herein in the specification and in the claims, should be understood to mean “either or both” of the elements so conjoined, i.e., elements that are conjunctively present in some cases and disjunctively present in other cases. Multiple elements listed with “and/or” should be construed in the same fashion, i.e., “one or more” of the elements so conjoined. Other elements may optionally be present other than the elements specifically identified by the “and/or” clause, whether related or unrelated to those elements specifically identified. Thus, as a non-limiting example, a reference to “A and/or B”, when used in conjunction with open-ended language such as “comprising” can refer, in one embodiment, to A only (optionally including elements other than B); in another embodiment, to B only (optionally including elements other than A); in yet another embodiment, to both A and B (optionally including other elements); etc.

As used herein in the specification and in the claims, “or” should be understood to have the same meaning as “and/or” as defined above. For example, when separating items in a list, “or” or “and/or” shall be interpreted as being inclusive, i.e., the inclusion of at least one, but also including more than one, of a number or list of elements, and, optionally, additional unlisted items. Only terms clearly indicated to the contrary, such as “only one of” or “exactly one of,” or, when used in the claims, “consisting of,” will refer to the inclusion of exactly one element of a number or list of elements. In general, the term “or” as used herein shall only be interpreted as indicating exclusive alternatives (i.e., “one or the other but not both”) when preceded by terms of exclusivity, such as “either,” “one of,” “only one of,” or “exactly one of.” “Consisting essentially of,” when used in the claims, shall have its ordinary meaning as used in the field of patent law.

As used herein in the specification and in the claims, the phrase “at least one,” in reference to a list of one or more elements, should be understood to mean at least one element selected from any one or more of the elements in the list of elements, but not necessarily including at least one of each and every element specifically listed within the list of elements and not excluding any combinations of elements in the list of elements. This definition also allows that elements may optionally be present other than the elements specifically identified within the list of elements to which the phrase “at least one” refers, whether related or unrelated to those elements specifically identified. Thus, as a non-limiting example, “at least one of A and B” (or, equivalently, “at least one of A or B,” or, equivalently “at least one of A and/or B”) can refer, in one embodiment, to at least one, optionally including more than one, A, with no B present (and optionally including elements other than B); in another embodiment, to at least one, optionally including more than one, B, with no A present (and optionally including elements other than A); in yet another embodiment, to at least one, optionally including more than one, A, and at least one, optionally including more than one, B (and optionally including other elements); etc.

In the claims, as well as in the specification above, all transitional phrases such as “comprising,” “including,” “carrying,” “having,” “containing,” “involving,” “holding,” “composed of,” and the like are to be understood to be open-ended, i.e., to mean including but not limited to. Only the transitional phrases “consisting of” and “consisting essentially of” shall be closed or semi-closed transitional phrases, respectively, as set forth in the United States Patent Office Manual of Patent Examining Procedures, Section 2111.03.

1. A method of preparing a recrystallized metal alloy comprising:
providing a cooling medium and a heating element to create a cold zone and a hot zone; and
drawing at least a portion of an additively manufactured preform in a draw direction from the cold zone towards the hot zone to form the recrystallized metal alloy;
wherein:
the cooling medium is provided as a liquid bath, a liquid spray, or a forced convection gas;
the cold zone and the hot zone create a surface temperature gradient on the at least a portion of the preform of at least about 10⁴ Km⁻¹; and
the step of drawing causes an average grain size of the at least a portion of the preform to increase in a direction parallel to the draw direction.

2. The method of claim 1, wherein: the preform comprises a superalloy comprising at least one of Ni, Co, Fe, or Nb.

3. The method of claim 1, wherein the preform comprises a magnetic material comprising at least one of Ni, Co, or Fe.

4. The method of claim 1, wherein:
the preform has a build axis corresponding to a build direction during additive manufacturing; and
during the step of drawing, the build axis of the preform is oriented parallel to the draw direction.

5. The method of claim 1, wherein the draw direction is a vertical direction.

6. The method of claim 1, wherein:
the cooling medium is provided as the liquid spray or the forced convection gas; and
the draw direction is a horizontal direction.

7. The method of claim 1, wherein the heating element comprises an induction coil, a resistive heater, an inductively heated susceptor, a laser beam, a focused light, or a flame.

8. The method of claim 1, wherein the surface temperature gradient is at least about 10⁵ K m⁻¹.

9. The method of claim 1, wherein:
prior to the step of drawing, the preform was additively manufactured by laser powder bed fusion (LPBF), electron beam additive manufacturing with point melting, or powder-fed directed energy deposition; and
after the preform was additively manufactured, the preform was not subjected to any heat treatments that substantially modify a dislocation density of the preform prior to the step of drawing.

10. The method of claim 1, wherein prior to the step of drawing, the preform has a dislocation density of about 10¹² to about 10¹⁴ m⁻².

11. The method of claim 1, wherein the step of drawing causes the average grain size to increase by at least a factor of 10.

12. The method of claim 1, wherein:
prior to the step of drawing, the preform has a crystallographic texture with at least 20% of grains oriented with a <100> direction parallel to the draw direction with a tolerance of 15° misorientation; and
the step of drawing substantially maintains the crystallographic texture in the additively manufactured preform.

13. The method of claim 1, further comprising incorporating functional grain structure grading into the metal alloy by:
varying a rate at which the at least a portion of the preform is drawn while performing the step of drawing;
selectively drawing only non-continuous portions of the at least a portion of the preform while performing the step of drawing; or
selectively heating non-continuous portions of the at least a portion of the preform.

14. The method of claim 1, wherein:
the metal alloy comprises at least one of IN738 or IN738LC;
the heating element heats the at least a portion of the preform to a temperature of about 1225°° C. to about 1250° C.; and
the step of drawing is performed at a draw rate of about 1.0 mm/hr to about 5.0 mm/hr.

15. An apparatus comprising:
a cooling medium having a heat transfer coefficient of about 100 W m⁻² K⁻¹ to about 40,000 W m⁻² K⁻¹;
a heating element configured to provide a hot zone capable of heating at least a portion of an additively manufactured preform; and
a means for drawing the at least a portion of the preform in a draw direction from the cooling medium through the hot zone;
wherein the cooling medium and the hot zone are capable of creating a surface temperature gradient on the at least a portion of the preform of at least about 10⁴ Km⁻¹.

16. The apparatus of claim 15, wherein:
the cooling medium is provided as at least one of a liquid bath, liquid spray, or a forced convection gas; and
the draw direction is a vertical direction.

17. The apparatus of claim 15, wherein:
the cooling medium is provided as a liquid spray or a forced convection gas; and
the draw direction is a horizontal direction.

18. A recrystallized metal alloy comprising at least one of Ni, Co, Fe, or Nb prepared by a process comprising:
additively manufacturing a preform along a build direction; and
directionally recrystallizing the preform to form the recrystallized metal alloy by drawing at least a portion of the preform in a draw direction parallel to the build direction from a cold zone provided by a cooling medium towards a hot zone provided by a heating element;
wherein the recrystallized metal alloy has an average grain size in the draw direction larger than an average grain size in the draw direction in the preform.

19. The recrystallized metal alloy of claim 18, wherein the step of additively manufacturing the preform comprises laser powder bed fusion (LPBF), electron beam additive manufacturing with point melting, or powder-fed directed energy deposition.

20. The recrystallized metal alloy of claim 18, wherein:
the preform has a dislocation density of about 10¹² to about 10¹⁴ m⁻²; and
the recrystallized metal alloy has a dislocation density of about 10¹⁰ to about 10¹² m⁻².

21. The recrystallized metal alloy of claim 18, wherein both the preform and the recrystallized metal alloy have a crystallographic texture with at least 20% of grains oriented with a <100> direction parallel to the draw direction with a tolerance of 15° misorientation.

22. The recrystallized metal alloy of claim 18, wherein the step of additively manufacturing the preform comprises incorporating a grain selector feature or single crystal seed into the preform.

23. The recrystallized metal alloy of claim 18, wherein the recrystallized metal alloy has at least one of a columnar grain structure or a single crystal grain structure.

24. The recrystallized metal alloy of claim 18, wherein the recrystallized metal alloy comprises a functional gradation of grain size and/or material composition.

25. The recrystallized metal alloy of claim 18, wherein the recrystallized metal alloy comprises at least one of IN738, IN738LC, A286, 718, 625, 909, 690, 600, H230, H282, HX, H188, 939, Rene65, Merl72, IN100, Rene108, CM247LC, 713C, Rene N2, Rene N4, Rene N5, Rene N6, CMSX4, CMSX10, RR1000, RR1073, C103, or ODS.
